(19) United States
(12) Patent Application Publication
(10) Pub. No.: US 2026/0296010 A1
(43) Pub. Date: Oct. 1, 2026

(54) PIEZOELECTRIC ELEMENT, LIQUID EJECTING HEAD, AND LIQUID EJECTING APPARATUS

(71) Applicant: SEIKO EPSON CORPORATION, Tokyo (JP)

(72) Inventors: Shu OKADA, CHINO-SHI (JP); Daisuke NAGANO, MATSUMOTO-SHI (JP); Yasuaki HAMADA, CHINO-SHI (JP)

(21) Appl. No.: 19/576,359

(22) Filed: Mar. 24, 2026

(30) Foreign Application Priority Data
Mar. 26, 2025 (JP) 2025-051950

(51) Int. Cl. B41J 2/14; B41J 2/045; H10N 30/00; H10N 30/20; H10N 30/50; H10N 30/853

(52) U.S. Cl. CPC B41J 2/14233; B41J 2/04541; B41J 2/04581; H10N 30/2047; H10N 30/50; H10N 30/708; H10N 30/8542; B41J 2002/14258

(57) ABSTRACT

A piezoelectric element includes: a lower electrode; a piezoelectric body; and an upper electrode, in which the piezoelectric body has a perovskite structure that includes at least K, Na, and Mn in an A-site and includes at least Nb and Mn in a B-site. In addition, a liquid ejecting head includes: a piezoelectric element; a pressure chamber in which liquid is flowed to apply a pressure to the liquid by the piezoelectric element; and a nozzle configured to eject the liquid using the pressure applied in the pressure chamber. In addition, a liquid ejecting apparatus includes: a liquid ejecting head; and a voltage application circuit configured to control driving of the piezoelectric element such that the liquid is ejected from the nozzle.

The present application is based on, and claims priority from JP Application Serial Number 2025-051950, filed Mar. 26, 2025, the disclosure of which is hereby incorporated by reference herein in its entirety.

### BACKGROUND

### 1. Technical Field

The present disclosure relates to a piezoelectric element, a liquid ejecting head, and a liquid ejecting apparatus.

### 2. Related Art

A liquid ejecting apparatus including a liquid ejecting head for ejecting ink onto a medium such as printing paper is proposed in the related art. For the liquid ejecting head, for example, a piezoelectric element for ejecting ink from a nozzle is used.

A piezoelectric element described in JP-A-2011-155272 includes a piezoelectric body formed of (KₐNa₁₋ₐ)NbO₃ including K, Na, and Nb. (KₐNa₁₋ₐ)NbO₃ has a perovskite structure represented by Formula ABO₃ and is abbreviated as KNN.

In a KNN piezoelectric body, a leakage current is likely to occur as compared to a lead zirconate titanate (PZT) piezoelectric body. In addition, since the KNN piezoelectric body is a lead-free piezoelectric material where the lead (Pb) content is suppressed, the biocompatibility is excellent, and the environmental burden is also small. To reduce the environmental burden, the KNN piezoelectric body that can suppress the occurrence of a leakage current is desired.

### SUMMARY

A piezoelectric element according to a preferred aspect of the present disclosure includes: a lower electrode; a piezoelectric body; and an upper electrode, in which the piezoelectric body has a perovskite structure that includes at least K, Na, and Mn in an A-site and includes at least Nb and Mn in a B-site.

A liquid ejecting head according to a preferred aspect of the present disclosure includes: a piezoelectric element; a pressure chamber in which liquid is flowed to apply a pressure to the liquid by the piezoelectric element; and a nozzle configured to eject the liquid using the pressure applied in the pressure chamber.

A liquid ejecting apparatus according to a preferred aspect of the present disclosure includes: a liquid ejecting head; and a driving circuit for driving the piezoelectric element.

### BRIEF DESCRIPTION OF THE DRAWINGS

FIG. 1 is a schematic view illustrating a configuration of a liquid ejecting apparatus according to a first embodiment.

FIG. 2 is an exploded perspective view of a liquid ejecting head illustrated in FIG. 1.

FIG. 3 is a cross-sectional view of a part of the liquid ejecting head illustrated in FIG. 2.

FIG. 4 is a diagram illustrating a diaphragm and a piezoelectric element of FIG. 3.

FIG. 5 is a table illustrating Examples.

FIG. 6 is a diagram illustrating a configuration example of the piezoelectric body illustrated in FIG. 4.

### DESCRIPTION OF EMBODIMENTS

Hereinafter, preferred embodiments according to the present disclosure will be described with reference to the accompanying drawings. In the drawings, dimensions or scales of each section are different from the actual dimensions or scales as appropriate, and some sections are schematically illustrated for easy understanding. Further, the scope of the present disclosure is not limited to these embodiments unless it is noted in the following description that the present disclosure is particularly limited. In addition, the phrase “the element α and the element β are laminated” means that the element α and the element β need only be arranged in an up-down direction, and whether the element α and the element β are in direct contact with each other is not a problem.

The following description will be made by using an X-axis, a Y-axis, and a Z-axis that intersect each other, as appropriate. One direction along the X-axis will be referred to as an X1 direction, and a direction opposite to the X1 direction will be referred to as an X2 direction. Directions opposite to each other along the Y-axis will be referred to as a Y1 direction and a Y2 direction. Directions opposite to each other along the Z-axis will be referred to as a Z1 direction and a Z2 direction. Viewing in a direction along the Z-axis will be referred to as a “plan view”. The Z-axis is typically a vertical axis. The Z1 direction is an upper side, and the Z2 direction is a lower side. Meanwhile, the Z-axis does not need to be the vertical axis. The X-axis, the Y-axis, and the Z-axis are typically orthogonal to each other, but are not limited thereto, and may intersect each other at, for example, an angle within a range of, for example, 80° or more and 100° or less.

### 1. First Embodiment

### 1-1. Overall Configuration of Liquid Ejecting Apparatus 100

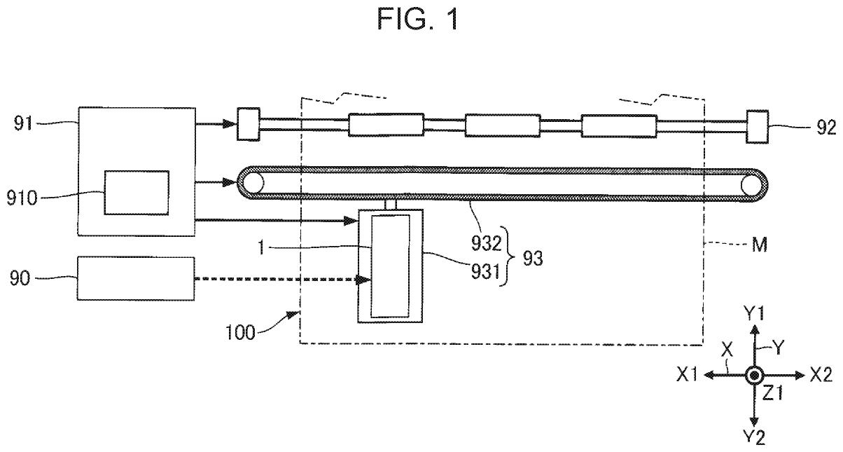

FIG. 1 is a configuration view schematically illustrating a liquid ejecting apparatus 100 according to a first embodiment. The liquid ejecting apparatus 100 is an ink jet printing apparatus that ejects ink, which is an example of liquid, to a medium M as liquid droplets. The medium M is typically printing paper. The medium M is not limited to the printing paper, and may be, for example, a printing target having any material such as a resin film or fabric.

As illustrated in FIG. 1, the liquid ejecting apparatus 100 is equipped with a liquid container 90 for storing the ink. Examples of specific aspects of the liquid container 90 include a cartridge that can be attached to and detached from the liquid ejecting apparatus 100, a bag-shaped ink pack formed of a flexible film, and an ink tank that can be refilled with the ink. A type of the ink stored in the liquid container 90 is optional. In addition, “liquid” may be any material that can be ejected from the liquid ejecting apparatus 100. For example, “liquid” may be a material where liquid includes solid matter.

The liquid ejecting apparatus 100 includes a controller 91, a transport mechanism 92, a moving mechanism 93, and a liquid ejecting head 1. The controller 91 includes, for example, a processing circuit such as a central processing unit (CPU) or a field programmable gate array (FPGA) and a storage circuit such as a semiconductor memory, and controls the operation of each element of the liquid ejecting apparatus 100. The controller 91 includes a voltage application circuit 910. The voltage application circuit 910 causes a nozzle to eject the ink by controlling driving of a piezoelectric element 5 described below. Specifically, the voltage application circuit 910 applies a reference voltage VBS and a driving voltage Com to the piezoelectric element 5 described below provided in the liquid ejecting head 1.

The transport mechanism 92 transports the medium M in the Y2 direction under the control of the controller 91. The moving mechanism 93 causes the liquid ejecting head 1 to reciprocate in the X1 direction and the X2 direction under the control of the controller 91. In the example illustrated in FIG. 1, the moving mechanism 93 includes a substantially box-shaped transport body 931 called a carriage that accommodates the liquid ejecting head 1, and a transport belt 932 to which the transport body 931 is fixed. The number of liquid ejecting heads 1 mounted on the transport body 931 is not limited to one, and may be plural. The liquid container 90 may be mounted on the transport body 931 in addition to the liquid ejecting head 1.

Under the control of the controller 91, the liquid ejecting head 1 ejects the ink supplied from the liquid container 90 to the medium M from each of a plurality of nozzles toward the Z2 direction. Although described below, the liquid ejecting head 1 includes a plurality of piezoelectric elements 5 for ejecting ink from a plurality of nozzles N. By performing the ejection in parallel with the transport of the medium M via the transport mechanism 92 and the reciprocating movement of the liquid ejecting head 1 via the moving mechanism 93, an image is formed at a surface of the medium M using the ink.

The liquid ejecting apparatus 100 includes the liquid ejecting head 1 and the voltage application circuit 910 described above. The liquid ejecting head 1 includes the piezoelectric element 5 having characteristics described below. In the piezoelectric element 5, the occurrence of a leakage current and a decrease in displacement characteristics are suppressed. Therefore, the liquid ejecting apparatus 100 including the piezoelectric element 5 has excellent reliability of the quality.

### 1-2. Overall Configuration of Liquid Ejecting Head 1

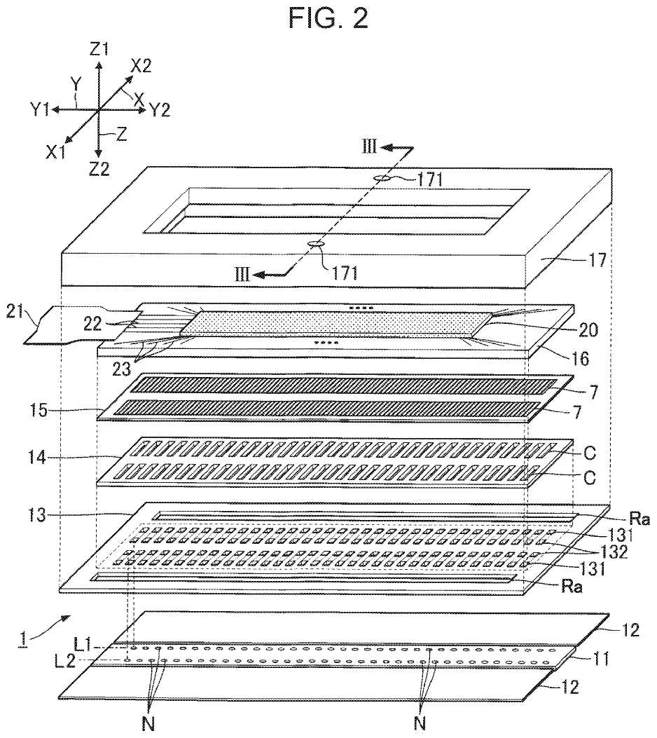

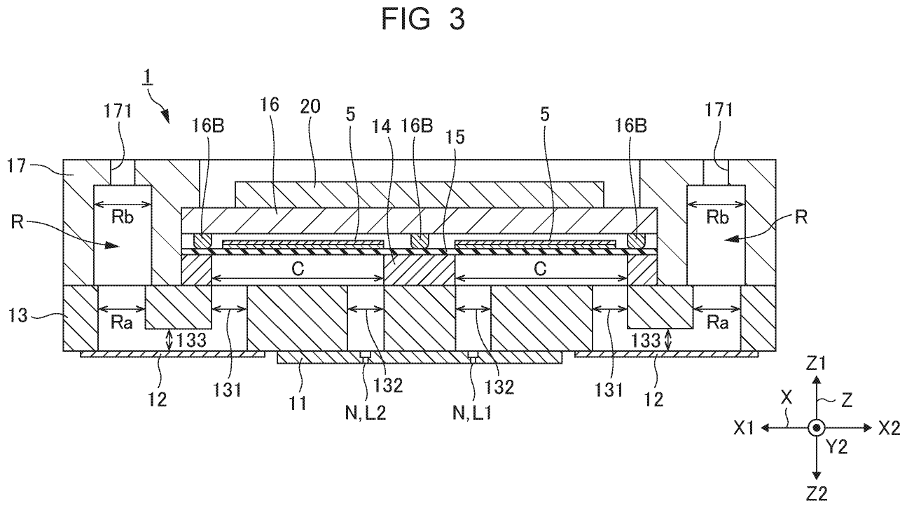

FIG. 2 is an exploded perspective view of the liquid ejecting head 1 illustrated in FIG. 1. FIG. 3 is a cross-sectional view of a part of the liquid ejecting head 1 illustrated in FIG. 2, and is a cross-sectional view taken along line III-III in FIG. 2.

As illustrated in FIG. 2, the liquid ejecting head 1 includes a plurality of nozzles N arranged in the direction along the Y-axis. In the example illustrated in FIG. 2, the plurality of nozzles N are divided into a first row L1 and a second row L2 arranged at intervals in the direction along the X-axis. Each of the first row L1 and the second row L2 is a set of the plurality of nozzles N linearly arranged in the direction along the Y-axis. An element related to each nozzle N in the first row L1 and an element related to each nozzle N in the second row L2 in the liquid ejecting head 1 are substantially symmetrical to each other in the direction along the X-axis. In the following description, the element corresponding to the first row L1 will be mainly described, and the description of the element corresponding to the second row L2 will be omitted as appropriate.

The positions of the plurality of nozzles N in the first row L1 and the positions of the plurality of nozzles N in the second row L2 in the direction along the Y-axis may be the same as or may be different from each other. In addition, the element related to each nozzle N in one of the first row L1 and the second row L2 may be omitted.

As illustrated in FIGS. 2 and 3, the liquid ejecting head 1 includes a nozzle plate 11, a vibration absorber 12, a flow path substrate 13, a pressure chamber substrate 14, a diaphragm 15, a wiring substrate 16, a housing portion 17, and a driving circuit 20. Each of the nozzle plate 11, the vibration absorber 12, the flow path substrate 13, the pressure chamber substrate 14, the diaphragm 15, the wiring substrate 16, and the housing portion 17 is a plate-shaped member that is elongated in the direction along the Y-axis. The nozzle plate 11, the flow path substrate 13, the pressure chamber substrate 14, the diaphragm 15, and the wiring substrate 16 are arranged in this order in the Z1 direction.

The nozzle plate 11 is a plate-shaped member in which the plurality of nozzles N are formed. Each of the plurality of nozzles N is a circular through-hole through which the ink passes. The nozzle N ejects the ink by the vibration of the diaphragm 15. The nozzle plate 11 is bonded to the flow path substrate 13 using, for example, an adhesive. The nozzle N is a portion that ejects the liquid using a pressure applied in a pressure chamber C.

The flow path substrate 13 is formed with a flow path for supplying the ink to the plurality of nozzles N. Specifically, in the flow path substrate 13, a space Ra, a plurality of supply flow paths 131, a plurality of communication flow paths 132, and a supply liquid chamber 133 are formed. The space Ra is an elongated opening extending in the direction along the Y-axis in a plan view when viewed in the direction along the Z-axis. Each of the supply flow paths 131 and the communication flow paths 132 is a through-hole formed for each nozzle N. The supply liquid chamber 133 is an elongated space extending in the direction along the Y-axis over the plurality of nozzles N, and allows the space Ra and the plurality of supply flow paths 131 to communicate with each other. Each of the plurality of communication flow paths 132 overlaps one nozzle N corresponding to the communication flow path 132 in a plan view. The pressure chamber substrate 14 is bonded to the flow path substrate 13 using, for example, an adhesive.

In the pressure chamber substrate 14, a plurality of pressure chambers C are provided. The plurality of pressure chambers C are arranged in the direction along the Y-axis. Each pressure chamber C is formed for each nozzle N, and is an elongated space extending in the direction along the X-axis in a plan view. The pressure chamber C is a space located between the flow path substrate 13 and the diaphragm 15. The pressure chamber C communicates with the nozzle N via the communication flow path 132 and communicates with the space Ra via the supply flow path 131 and the supply liquid chamber 133. The pressure chamber C is a portion in which liquid is flowed to apply a pressure to the liquid by the piezoelectric element 5.

Each of the nozzle plate 11, the flow path substrate 13, and the pressure chamber substrate 14 is manufactured by processing a silicon single crystal substrate using, for example, dry etching or wet etching. However, other known methods may be used as appropriate for manufacturing the nozzle plate 11, the flow path substrate 13, and the pressure chamber substrate 14.

The diaphragm 15 is disposed on a surface of the pressure chamber substrate 14 facing the Z1 direction. The diaphragm 15 is a plate-shaped member that can elastically vibrate.

A plurality of piezoelectric elements 5 corresponding to the nozzles N are disposed on a surface of the diaphragm 15 facing the Z1 direction. Each piezoelectric element 5 has an elongated shape extending in the direction along the X-axis in a plan view. The plurality of piezoelectric elements 5 correspond to the plurality of pressure chambers C, and are arranged in the direction along the Y-axis. The piezoelectric element 5 is deformed due to the application of a voltage. When the diaphragm 15 vibrates in conjunction with the deformation, the pressure in the pressure chamber C fluctuates, so that the ink is ejected from the nozzle N.

The housing portion 17 is a case for storing the ink supplied to the plurality of pressure chambers C. As illustrated in FIG. 3, a space Rb is formed in the housing portion 17. The space Rb of the housing portion 17 and the space Ra of the flow path substrate 13 communicate with each other. A space formed by the space Ra and the space Rb functions as a liquid storage chamber R that is a reservoir that stores the ink supplied to the plurality of pressure chambers C. The ink is supplied to the liquid storage chamber R through an inlet 171 formed in the housing portion 17. The ink in the liquid storage chamber R is supplied to the pressure chamber C through the supply liquid chamber 133 and each supply flow path 131.

The vibration absorber 12 is a flexible film that forms a wall surface of the liquid storage chamber R. The vibration absorber 12 is a compliance substrate that absorbs the fluctuation in the pressure of the ink in the liquid storage chamber R.

The wiring substrate 16 is a plate-shaped member in which wirings for electrically coupling the driving circuit 20 and the plurality of piezoelectric elements 5 are formed. A surface of the wiring substrate 16 facing the Z2 direction is bonded to the diaphragm 15 via a plurality of conductive bumps 16B. On the other hand, the driving circuit 20 is mounted on a surface of the wiring substrate 16 facing the Z1 direction. The driving circuit 20 is an integrated circuit (IC) chip that outputs the driving voltage Com and the reference voltage VBS for driving each piezoelectric element 5.

As illustrated in FIG. 2, an end portion of an external wiring 21 is bonded to a surface of the wiring substrate 16 facing the Z1 direction. The external wiring 21 is formed of, for example, coupling components such as flexible printed circuits (FPC) or flexible flat cables (FFC). The wiring substrate 16 is formed with a plurality of wirings 22 that electrically couple the external wiring 21 and the driving circuit 20, and a plurality of wirings 23 to which the driving voltage Com and the reference voltage VBS output from the driving circuit 20 are supplied.

The wiring substrate 16 is not limited to a rigid substrate, and may be, for example, flexible printed circuits (FPC) or a flexible flat cable (FFC). In this case, the wiring substrate 16 may also serve as the external wiring 21.

In this liquid ejecting head 1, when the piezoelectric elements 5 are bent and deformed due to the application of a voltage, the diaphragm 15 is bent and deformed, that is, vibrates, in a direction in which the volume of the pressure chambers C decreases. As a result, the pressure in the pressure chambers C changes, and the ink in the pressure chambers C is ejected from the nozzle N. The piezoelectric element 5 returns to the original position after the ink is ejected.

The liquid ejecting head 1 includes the piezoelectric element 5, the pressure chamber C in which ink that is liquid is flowed to apply a pressure to the ink by the piezoelectric element 5, and the nozzle N that eject the ink using a pressure applied in the pressure chamber C. The liquid ejecting head 1 includes the piezoelectric element 5 having the characteristics described below. Therefore, the occurrence of a leakage current can be suppressed. Accordingly, the liquid ejecting head 1 having high quality can be provided.

In addition, the liquid ejecting head 1 includes all of each of the elements illustrated in FIG. 3. However, the components of the liquid ejecting head 1 do not need to include all of the elements and may further include additional elements.

### 1-3. Diaphragm 15 and Piezoelectric Element 5

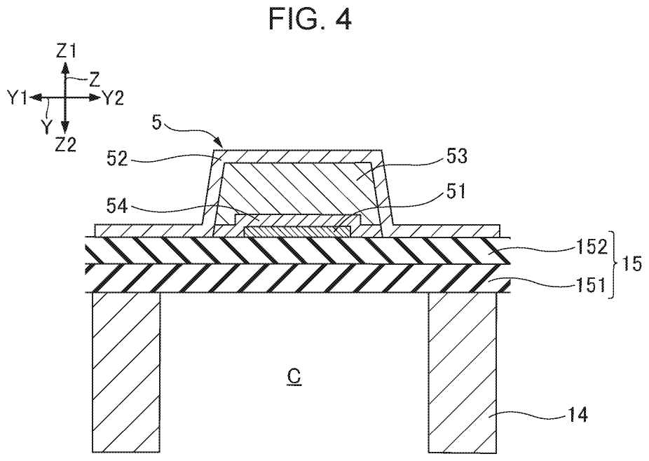

FIG. 4 is a cross-sectional view illustrating the diaphragm 15 and the piezoelectric element 5 of FIG. 3. In the example illustrated in FIG. 4, the diaphragm 15 is formed of a laminate including a first vibration layer 151 and a second vibration layer 152. The first vibration layer 151 is in contact with the pressure chamber substrate 14. The second vibration layer 152 is disposed above the first vibration layer 151. The first vibration layer 151 is formed of an elastic material such as silicon oxide (SiOₓ). The second vibration layer 152 is formed of an insulating material such as zirconium oxide (ZrOₓ). The first vibration layer 151 is formed, for example, by thermally oxidizing a part of the pressure chamber substrate 14. The second vibration layer 152 is formed, for example, by a known film forming technique such as sputtering. The diaphragm 15 may be formed of a single layer or may be formed of three or more layers.

The piezoelectric element 5 is provided on the diaphragm 15. The piezoelectric element 5 mainly includes a lower electrode 51, a piezoelectric body 53, an upper electrode 52, and a seed layer 54. The lower electrode 51, the seed layer 54, the piezoelectric body 53, and the upper electrode 52 are provided to be arranged along the Z2 direction that is a lamination direction.

The lower electrode 51 is provided above the diaphragm 15. The lower electrode 51 is an individual electrode provided for each piezoelectric element 5. The driving voltage Com that fluctuates is applied to the lower electrode 51. The lower electrode 51 is elongated along the X-axis. A plurality of lower electrodes 51 are arranged along the Y-axis at intervals. The lower electrode 51 includes, for example, a conductive material such as platinum (Pt). The thickness of the lower electrode 51 along the Z-axis is not particularly limited, and is, for example, 50 nm or more and 120 nm or less. In addition, the lower electrode 51 may be formed of a single layer or may be formed of a plurality of layers. The lower electrode 51 is formed using a sputtering method.

The seed layer 54 is provided for controlling an orientation of the piezoelectric body 53. The thickness of the seed layer 54 along the Z-axis is less than the thickness of the piezoelectric body 53 along the Z-axis. The thickness of the seed layer 54 along the Z-axis is not particularly limited, and is, for example, 5 nm or more and 50 nm or less. In addition, the seed layer 54 may be formed of a single layer or may be formed of a plurality of layers. The seed layer 54 is formed using a sputtering method or a solution method.

For example, the seed layer 54 has a Perovskite structure. The seed layer 54 includes, for example, lead titanate PbₐTi_{b}O_{z}, lanthanum nickel oxide LaₐNi_{b}O_{z}, PbₓBi₍ₐ₋ₓ₎ Fe_{y}Ti_{(b-y)}O_{z}, BiₐFe_{y}Ti_{(b-y)}O_{z}, or PbₐFe_{y}Ti_{(b-y)}O_{z}. In the above-described chemical formulae, it is necessary to satisfy 0<x<a and 0<y<b. In addition, the seed layer 54 may include a composite oxide having a perovskite structure including Bi, Fe, and Ti. In particular, it is preferable that the seed layer 54 includes PbₓBi₍ₐ₋ₓ₎Fe_{y}Ti_{(b-y)}O_{z}. PbₓBi₍ₐ₋ₓ₎Fe_{y}Ti_{(b-y)}O_{z} is more preferable due to its excellent orientation controllability.

The piezoelectric body 53 is, for example, a strip-shaped dielectric film that is continuous along the Y-axis across the plurality of piezoelectric elements 5. The piezoelectric body 53 has, for example, a strip shape extending along the Y-axis and is separated for each piezoelectric element 5 by forming a plurality of notches. The thickness of the piezoelectric body 53 along the Z-axis is not particularly limited, and is, for example, 300 nm or more and 1500 nm or less.

The piezoelectric body 53 includes a piezoelectric material. The piezoelectric body 53 is manufactured, for example, using a metal organic decomposition (MOD) method or a solution method such as a sol-gel method. The sol-gel method is a method of applying a precursor solution formed of a sol to the lower layer to form a piezoelectric precursor film, and drying and degreasing the piezoelectric precursor film at a predetermined temperature. In addition, the MOD method is a method of applying a MOD solution to the lower layer and drying and degreasing the MOD solution.

The upper electrode 52 is provided above the piezoelectric body 53. The upper electrode 52 is a strip-shaped common electrode that extends along the Y-axis so as to be continuous across the plurality of the piezoelectric elements 5. The predetermined reference voltage VBS is applied to the upper electrode 52. The upper electrode 52 includes, for example, a conductive material such as iridium (Ir). The thickness of the upper electrode 52 along the Z-axis is not particularly limited, and is, for example, 50 nm or more and 120 nm or less. In addition, the upper electrode 52 may be formed of a single layer or may be formed of a plurality of layers. The upper electrode 52 is formed using a sputtering method.

In the piezoelectric element 5, a voltage corresponding to a difference between the reference voltage VBS applied to the upper electrode 52 and the driving voltage Com corresponding to the ejection amount supplied to the lower electrode 51 is applied to the piezoelectric body 53. By applying a voltage between the lower electrode 51 and the upper electrode 52, the piezoelectric body 53 deforms such that the piezoelectric element 5 is bent and deformed, that is, vibrates.

In the present embodiment, the lower electrode 51 is an individual electrode and the upper electrode 52 is a common electrode. However, the lower electrode 51 may be a common electrode, and the upper electrode 52 may be an individual electrode.

### 1-4. Piezoelectric Body 53

The piezoelectric body 53 includes K, Na, and Nb. Specifically, the piezoelectric body 53 includes a composite oxide including potassium sodium niobate ((KₐNa₁₋ₐ)NbO₃). (KₐNa₁₋ₐ)NbO₃ has a perovskite structure represented by Formula ABO₃ and is abbreviated as KNN. a satisfies 0.1≤a≤0.9. Accordingly, the piezoelectric body 53 includes a KNN-based composite oxide. KNN is a solid solution of KNbO₃ and NaNbO₃. In the KNN, the A-site is occupied with K and Na, and the B-site is occupied with Nb.

In addition, since the KNN-based composite oxide is a lead-free piezoelectric material where the content of lead (Pb) or the like is suppressed, the biocompatibility is excellent, and the environmental burden is also small. Further, the KNN-based composite oxide has excellent piezoelectric characteristics among lead-free piezoelectric materials, which is advantageous in improving various characteristics.

In the KNN, a leakage current is likely to occur as compared to lead zirconate titanate (PZT), and displacement characteristics are small. However, in order to reduce the environmental burden, it is desired to use the KNN. Accordingly, it is desired to improve displacement characteristics while suppressing the occurrence of a leakage current in the KNN piezoelectric body.

As a result of a thorough investigation by the present inventors, it was found that the KNN piezoelectric body includes Mn such that the occurrence of a leakage current can be suppressed. Specifically, it was found that the occurrence of a leakage current can be suppressed by substituting K and Na that are the A-site elements and Nb that is the B-site element in a crystal lattice instead of causing Mn to be present in a grain boundary with Mn.

In particular, by substituting K and Na that are the A-site elements with Mn, the occurrence of a leakage current can be reduced. However, when K and Na that are the A-site elements are substituted with Mn, there are the following disadvantages.

Each of ionic radii of K and Na in the A-site is more than the ionic radius of Mn. Accordingly, K and Na in the A-site is substituted with Mn having a smaller ionic radius. For example, the ionic radius of K1+ is 1.64 Å, and the ionic radius of Na1+ is 1.39 Å. On the other hand, the ionic radius of Mn2+ is 1.27 Å, the ionic radius of Mn3+ is 1.035 Å, and the ionic radius of Mn4+ is 0.95 Å.

By substituting K and Na in the A-site with Mn having a smaller ionic radius, a space where the element in the B-site divided by the A-site element is movable decreases. In the piezoelectric body 53, the B-site element is displaced by being moved in the lattice of the A-site element. Therefore, when this space is excessively small, the displacement characteristics decrease.

In addition, when Nb that is the B-site element is substituted with Mn, the effect of reducing a leakage current is smaller as compared to when K and Na that are the A-site elements are substituted with Mn.

In consideration of the above-described facts, the piezoelectric body 53 includes Mn in both of the A-site elements and the B-site elements of KNN. That is, the piezoelectric body 53 has a perovskite structure that includes at least K, Na, and Mn in the A-site and includes at least Nb and Mn in the B-site.

By allowing the piezoelectric body 53 to have the above-described perovskite structure, a decrease in displacement characteristics caused by the addition of Mn can be suppressed while suppressing the occurrence of a leakage current.

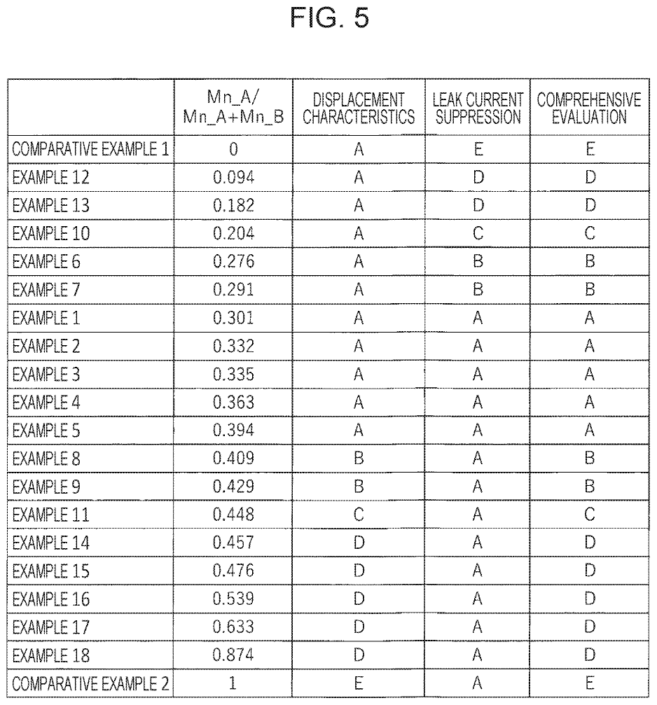

FIG. 5 is a table illustrating Examples. In FIG. 5, when an amount of Mn positioned in the A-site of the piezoelectric body 53 is represented by Mn_A and an amount of Mn positioned in the B-site of the piezoelectric body 53 is represented by Mn_B, Mn_A/(Mn_A+Mn_B) is shown. In Examples 1 to 18 and Comparative Examples 1 and 2 of FIG. 5, by adding Mn and Cu to KNN and varying the addition amounts of Mn and Cu, the distribution ratios in the A-site and the B-site are varied. In this specification, Mn_A and Mn_B represent the amounts of manganese occupying the A-site and the B-site in the perovskite lattice after crystallization. These ratios can be measured by solid-state analytical techniques such as ALCHEMI (Analytical Electron Microscopy).

In addition, in FIG. 5, the evaluation for Mn_A/(Mn_A+Mn_B) is shown. Specifically, as the evaluation, evaluation regarding the displacement characteristics, evaluation regarding the suppression of a leakage current, and comprehensive evaluation thereof are shown.

The evaluation regarding the displacement characteristics is performed by evaluating the deficiency of the ejection amount from an ideal ejection amount. The ideal ejection amount is the amount of ink that is desired to be ejected for each ejection.
A: the deficiency of the ejection amount from the ideal ejection amount was not substantially found.
B: a deficiency of about 3% to 10% from the ideal ejection amount was found.
C: a deficiency of 10% or more from the ideal ejection amount was found.
D: a deficiency of 20% or more from the ideal ejection amount was found.
E: a deficiency of 30% or more from the ideal ejection amount was found.

The evaluation regarding the suppression of a leakage current is performed by repeatedly applying a voltage to the piezoelectric body 53 multiple times and using a difference in current between the first voltage application and the final voltage application.
A: there was no difference in current between the voltage applications.
B: there was substantially no difference in current between the voltage applications.
C: a small difference in current between the voltage applications was found but was allowable.
D: a difference in current between the voltage applications was found.
E: a significant difference in current between the voltage applications was found.

The comprehensive evaluation was performed using the evaluation regarding the displacement characteristics and the evaluation regarding the suppression of a leakage current. The evaluation was performed using five grades of A, B, C, D, and E in order from the example having the highest quality. A has the highest quality.

In each of Examples, both of the A-site elements and the B-site elements include Mn. On the other hand, in Comparative Example 1, the A-site elements do not include Mn, and the B-site elements include Mn. In addition, in Comparative Example 2, the A-site elements include Mn, and the B-site elements do not include Mn.

Each of Examples is excellent in the evaluation regarding the displacement characteristics, the evaluation regarding a leakage current, and the comprehensive evaluation thereof as compared to Comparative Examples 1 and 2. Accordingly, as can be seen from FIG. 5, the piezoelectric body 53 include Mn in both of the A-site elements and the B-site elements. As a result, while suppressing the occurrence of a leakage current, a decrease in displacement characteristics can be suppressed.

Further, by adjusting the Mn ratio in the A-site elements and the B-site elements, the occurrence of a leakage current and a decrease in displacement characteristics can be more effectively suppressed.

Specifically, it is preferable that the piezoelectric body 53 satisfies Mn_A/(Mn_A+Mn_B)<0.45. Examples 1 to 13 satisfy Mn_A/(Mn_A+Mn_B)<0.45. Examples 1 to 13 are excellent in the evaluation regarding the displacement characteristics as compared to the other Examples. Accordingly, by satisfying Mn_A/(Mn_A+Mn_B)<0.45, a decrease in displacement characteristics can be effectively suppressed as compared to when Mn_A/(Mn_A+Mn_B)<0.45 is not satisfied.

Further, it is preferable that the piezoelectric body 53 satisfies Mn_A/(Mn_A+Mn_B)<0.40. Examples 1 to 7, 10, 12, and 13 satisfy Mn_A/(Mn_A+Mn_B)<0.40. In Examples 1 to 7, 10, 12, and 13, the evaluation regarding the displacement characteristics is A. Accordingly, by satisfying Mn_A/(Mn_A+Mn_B)<0.40, a decrease in displacement characteristics can be more effectively suppressed as compared to when Mn_A/(Mn_A+Mn_B)<0.40 is not satisfied.

In addition, it is preferable that the piezoelectric body 53 satisfies 0.20<Mn_A/(Mn_A+Mn_B)<0.45. Examples 1 to 11 satisfy 0.20<Mn_A/(Mn_A+Mn_B)<0.45. In Examples 1 to 11, a decrease in displacement characteristics can be suppressed while suppressing the occurrence of a leakage current as compared to the other Examples. Accordingly, by satisfying 0.20<Mn_A/(Mn_A+Mn_B)<0.45, a decrease in displacement characteristics can be more effectively suppressed while suppressing the occurrence of a leakage current as compared to when 0.20<Mn_A/(Mn_A+Mn_B)<0.45 is not satisfied.

Further, it is preferable that the piezoelectric body 53 satisfies 0.30<Mn_A/(Mn_A+Mn_B)<0.45. Examples 1 to 5 satisfy 0.30<Mn_A/(Mn_A+Mn_B)<0.450. Examples 1 to 5 is excellent in all the evaluation results as compared to the other Examples. Accordingly, by satisfying 0.30<Mn_A/(Mn_A+Mn_B)<0.45, a decrease in displacement characteristics can be more effectively suppressed while suppressing the occurrence of a leakage current as compared to when 0.30<Mn_A/(Mn_A+Mn_B)<0.45 is not satisfied. The piezoelectric body 53 having a particularly high quality can be provided.

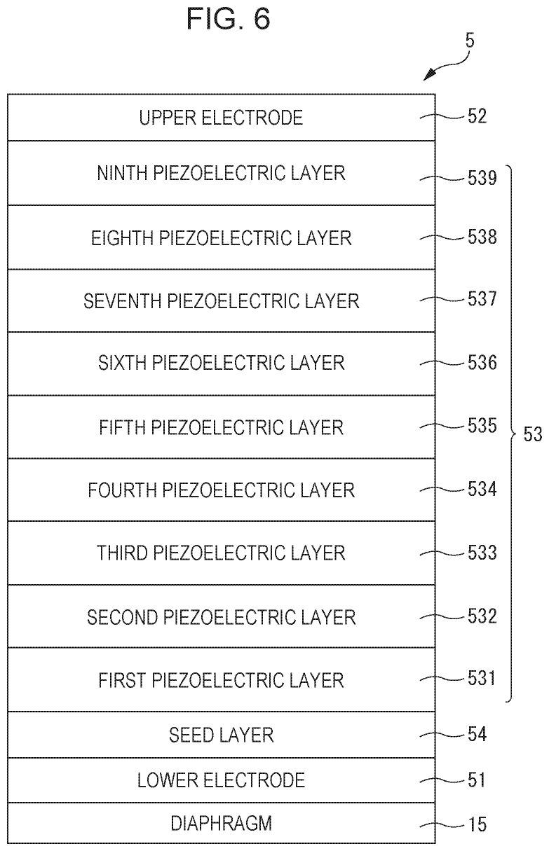

FIG. 6 is a diagram illustrating a configuration example of the piezoelectric body 53 illustrated in FIG. 4. As illustrated in FIG. 6, the piezoelectric body 53 is formed, for example, by laminating a plurality of piezoelectric layers. In the example of FIG. 6, the piezoelectric body 53 is formed of a laminate of nine piezoelectric layers including a first piezoelectric layer 531, a second piezoelectric layer 532, a third piezoelectric layer 533, a fourth piezoelectric layer 534, a fifth piezoelectric layer 535, a sixth piezoelectric layer 536, a seventh piezoelectric layer 537, an eighth piezoelectric layer 538, and a ninth piezoelectric layer 539. The number of the piezoelectric layers is not limited to 9 and may be any number. The piezoelectric body 53 may be formed of a single layer.

The piezoelectric body 53 includes at least a first region and a second region that is laminated on the first region. In the example illustrated in the drawing, the first region is an inner region of each of the piezoelectric layers. That is, the first region is the inner region of each of the first piezoelectric layer 531 to the ninth piezoelectric layer 539. The second region is a boundary region between two adjacent piezoelectric layers. For example, the second region is a region including a boundary between the first piezoelectric layer 531 and the second piezoelectric layer 532. In addition, for example, the second region is a region including a boundary between the second piezoelectric layer 532 and the third piezoelectric layer 533.

An amount of Mn positioned in the A-site of the first region is represented by Mn_A1 and an amount of Mn positioned in the B-site of the first region is represented by Mn_B1, and an amount of Mn positioned in the A-site of the second region is represented by Mn_A2 and an amount of Mn positioned in the B-site of the second region is represented by Mn_B2. In this case, it is preferable that Mn_A1/(Mn_A1+Mn_B1)>Mn_A2/(Mn_A2+Mn_B2) is satisfied. That is, the Mn ratio in the A-site of the first region is more than that of the second region.

By satisfying Mn_A1/(Mn_A1+Mn_B1)>Mn_A2/(Mn_A2+Mn_B2), as in each of Examples, the Mn ratio in the A-site elements and the B-site elements is easily adjusted as compared to when Mn_A1/(Mn_A1+Mn_B1)>Mn_A2/(Mn_A2+Mn_B2) is not satisfied.

In addition, when the piezoelectric body 53 is formed of a plurality of layers, the abundances of K and Na in the A-site vary in the layer. It is preferable that a ratio of an amount of K to an amount of Na in the first region is less than a ratio of an amount of K to an amount of Na in the second region. That is, K/Na in the first region is less than K/Na in the second region.

As described above, the ionic radius of K1+ is 1.64 Å, and the ionic radius of Na1+ is 1.39 Å. The ionic radius of K1+ is more than the ionic radius of Na1+. In the layer where the amount of K is large, the ionic radius of the A-site is large. Therefore, the space of the B-site surrounded by the A-site is widened. Thus, Mn is likely to be substituted with the B-site. On the other hand, when the amount of Na increases, the B-site space is narrowed, and Mn is not likely to enter into the B-site. Instead, Mn is likely to enter into the A-site. By using this phenomenon, the distribution ratio to the A-site and the B-site can be controlled due to a balance between Na and K in the piezoelectric body 53.

Accordingly, when K/Na in the first region is less than K/Na in the second region, by satisfying Mn_A1/(Mn_A1+Mn_B1)>Mn_A2/(Mn_A2+Mn_B2), as in each of Examples, the Mn ratio in the A-site and the B-site is easily adjusted.

In addition, the above-described piezoelectric body 53 may include at least K, Na, and Mn in an A-site and may include at least Nb and Mn in a B-site. Accordingly, metallic elements other than the above-described elements may be added to the A-site and the B-site. Examples of the metallic elements to be added include lithium (Li), barium (Ba), calcium (Ca), strontium (Sr), zirconium (Zr), titanium (Ti), bismuth (Bi), tantalum (Ta), antimony (Sb), Iron (Fe), cobalt (Co), silver (Ag), magnesium (Mg), zinc (Zn), and copper (Cu). The number of types of the metallic elements to be added may be one or plural.

In addition, the piezoelectric material forming the piezoelectric body 53 may be a mixed crystal including the KNN-based composite oxide and another composite oxide having a perovskite structure represented by ABO₃.

### 2. Modified Examples

The embodiments described above may be modified in various ways. A specific modification aspect that can be applied to the embodiments described above will be described below. Two or more aspects optionally selected from the following examples can be combined as appropriate within a range in which the aspects are not mutually contradictory.

The “liquid ejecting head” may be a circulation type head having a so-called circulation flow path.

The “liquid ejecting apparatus” may be adopted in various devices such as facsimile devices and copy machines, in addition to devices dedicated to printing. The application of the liquid ejecting apparatus is not limited to printing. For example, liquid ejecting apparatuses that eject a coloring material solution are used as manufacturing apparatuses that form a color filter for display devices such as liquid crystal display panels. In addition, a liquid ejecting apparatus that ejects a solution of a conductive material is used as a manufacturing apparatus that forms a wiring or an electrode on a wiring substrate. In addition, liquid ejecting apparatuses that eject a solution of an organic substance related to a living body are used, for example, as manufacturing devices for manufacturing biochips.

The piezoelectric element according to the present disclosure is not limited to the liquid ejecting head or the liquid ejecting apparatus, and may be a device having a function of converting a voltage and a mechanical force to each other, for example, applying a voltage to generate a mechanical force or applying a mechanical force to generate a voltage. The piezoelectric element according to the present disclosure may be, for example, an ultrasonic motor, a vibration type dust removing device, a piezoelectric transformer, a piezoelectric speaker, a piezoelectric pump, an ultrasonic wave detector, an angular velocity sensor, an acceleration sensor, a vibration sensor, an inclination sensor, a pressure sensor, a collision sensor, a human sensor, an infrared sensor, a terahertz sensor, a heat detection sensor, a pyroelectric sensor, a piezoelectric sensor, a ferroelectric memory (FeRAM), a ferroelectric transistor (FeFET), a ferroelectric logic (FeLogic) circuit, a ferroelectric capacitor, a wavelength converter, an optical waveguide, an optical path modulator, a refractive index control element, or an electronic shutter mechanism.

The present disclosure is described above based on the preferred embodiments, but the present disclosure is not limited to the above embodiments. In addition, the configuration of each portion of the present disclosure can be replaced with any configuration having the same function in the above-described embodiments, and any configuration can be added.

What is claimed is:

1. A piezoelectric element comprising:
a lower electrode;
a piezoelectric body; and
an upper electrode, wherein
the piezoelectric body has a perovskite structure that includes at least K, Na, and Mn in an A-site and includes at least Nb and Mn in a B-site.

2. The piezoelectric element according to claim 1, wherein when an amount of Mn positioned in the A-site of the piezoelectric body is represented by Mn_A and an amount of Mn positioned in the B-site of the piezoelectric body is represented by Mn_B, Mn_A/(Mn_A+Mn_B)<0.45 is satisfied.

3. The piezoelectric element according to claim 1, wherein Mn_A/(Mn_A+Mn_B)<0.40 is satisfied.

4. The piezoelectric element according to claim 2, wherein Mn_A/(Mn_A+Mn_B)>0.20 is satisfied.

5. The piezoelectric element according to claim 4, wherein Mn_A/(Mn_A+Mn_B)>0.30 is satisfied.

6. The piezoelectric element according to claim 1, wherein
the piezoelectric body includes at least a first region and a second region that is laminated on the first region, and
when an amount of Mn positioned in the A-site of the first region is represented by Mn_A1 and an amount of Mn positioned in the B-site of the first region is represented by Mn_B1, and
when an amount of Mn positioned in the A-site of the second region is represented by Mn_A2 and an amount of Mn positioned in the B-site of the second region is represented by Mn_B2,
Mn_A1/(Mn_A1+Mn_B1)>Mn_A2/(Mn_A2+Mn_B2) is satisfied.

7. The piezoelectric element according to claim 6, wherein
the piezoelectric body is formed by laminating a plurality of piezoelectric layers,
the first region is an inner region of the piezoelectric layer, and
the second region is a boundary region of the piezoelectric layer.

8. The piezoelectric element according to claim 6, wherein a ratio of an amount of K to an amount of Na in the first region is less than a ratio of an amount of K to an amount of Na in the second region.

9. A liquid ejecting head comprising:
the piezoelectric element according to claim 1;
a pressure chamber in which liquid is flowed to apply a pressure to the liquid by the piezoelectric element; and
a nozzle configured to eject the liquid using the pressure applied in the pressure chamber.

10. A liquid ejecting apparatus comprising:
a liquid ejecting head according to claim 9; and
a voltage application circuit configured to control driving of the piezoelectric element such that the liquid is ejected from the nozzle.
